(19) United States
(12) Patent Application Publication
(10) Pub. No.: US 2026/0016517 A1
(43) Pub. Date: Jan. 15, 2026

(54) SYSTEM AND METHOD OF MANAGING UTILIZATION OF POWER CONSUMERS IN AN ELECTRIC VEHICLE

(71) Applicant: V-HOLA Labs Ltd., Kfar Saba (IL)

(72) Inventor: Asaf TSIN, Kfar Saba (IL)

(73) Assignee: V-HOLA Labs Ltd., Kfar Saba (IL)

(21) Appl. No.: 18/994,857

(22) PCT Filed: Jul. 19, 2023
(86) PCT No.: PCT/IL2023/050756

§ 371 Date: Jan. 15, 2025

Related U.S. Application Data
(60) Provisional application No. 63/390,429, filed on Jul. 19, 2022.

(51) Int. Cl. G01R 22/10; B60L 1/00; G01R 33/02

(52) U.S. Cl. CPC G01R 22/10; B60L 1/00; G01R 33/0206; B60L 2270/147

(57) ABSTRACT

A system and a method of managing utilization of power consumers in a vehicle, by at least one processor is disclosed. The method comprises: (a) obtaining, from one or more in-vehicle data sources, a first driving profile representing utilization of power consumers in the vehicle; (b) calculating an Electro-Magnetic Field (EMF) data element, representing emission of EMF by the power consumers of the first driving profile; and (c) calculating a second driving profile based on (i) the first driving profile and (ii) the EMF data element, wherein the second driving profile represents another utilization of power consumers in the vehicle.

### CROSS-REFERENCE TO RELATED APPLICATIONS

This application is an International Patent application that claims the benefit of priority of U.S. Provisional Patent Application No. 63/390,429, filed 19 Jul. 2022, which is hereby incorporated by reference in their entirety.

### FIELD OF THE INVENTION

The present invention relates generally to a method of managing the utilization of power consumers in a vehicle. More specifically, the present invention relates to a system and a method of managing the utilization of power consumers in a vehicle to reduce Electro-Magnetic Field (EMF) emissions and/or power consumption.

### BACKGROUND OF THE INVENTION

Electric vehicles are the transportation means of the future. Electric and hybrid cars and trains are already run in millions on roads all over the world, and electric airplanes and ships are under development. These vehicles include many electrotechnical and electrical components that emit electromagnetic (EM) emissions. The EM emission includes a magnetic flux which depends on the current consumption of each electrical component, as shown for a simple wire component in equation (1):

$$\vert \vec{{B}_{j}} \vert = \vert \frac{{μ}_{0} \vec{ι}}{2 π r} \vert \qquad ( 1 )$$

Wherein, \vec{B} is the magnetic field vector generated by radiation component j (j=1 to M), i the current flowing in, to, or from an electric component, and r the distance from the radiating component.

The accumulated magnetic fields per frequency in one frequency scan at a certain location (e.g., in a vehicle) can be determined according to equation (2)

$${\sum }_{j = 1 H 𝓏}^{10 MH 𝓏} \frac{{B}_{j}}{( {B}_{ij} )} \leq 1 \qquad ( 2 )$$

where
Bⱼ=the magnetic flux density at frequency j;
B_{Lj}=the magnetic flux density reference level:

The reference level for General Public exposure to magnetic fields, at various frequencies ranges up to 10 MH, according to ICNIRP Standard for General Public, 1998, are given in table 1.

TABLE 1

| Reference levels for General | |
|---|---|
| Public exposure to time-varying | |
| magnetic fields up to 10 MHz | |
| varying with the frequency (f). | |
| Frequency range | B field (μT) |
| Up to 1 Hz | 4 × 10\hat{ }4 |

| | | |
|---|---|---|
| 1-8 | Hz | 4 × 10\hat{ }4/f\hat{ }2 |
| 8-25 | Hz | 5000/f |

| | |
|---|---|
| 0.025 kHz-0.8 kHz | 5/f |

| | | |
|---|---|---|
| 0.8-3 | kHz | 6.25 |
| 3-150 | kHz | 6.25 |
| 0.15-1 | MHz | 0.92/f |
| 1-10 | MHz | 0.92/f |

The International Electrotechnical Commission (IEC) has established in 2013 a working group targeting the method and protocol for measuring EMF in vehicles. The IEC 62764-1 protocol includes measurement procedures of magnetic field levels generated by electronic and electrical equipment in the automotive environment, low frequencies 1 Hz-400 KHz, with respect to human exposure.

In order to manufacture an electric vehicle that will be safe for humans in all times, with improved power consumption, there is a need to consciously monitor the EMF and the power consumption of the various electricity consumers in the vehicle. Adding an array of sensors to each vehicle is less practical.

Accordingly, there is a need for a “virtual” EMF and power consumption sensor that can correlate between the currently operating electricity consumers in the vehicle, the driving conditions, and the expected EMF and power consumption.

### SUMMARY OF THE INVENTION

Some aspects of the invention may be related to a system and a method of managing utilization of power consumers in a vehicle, by at least one processor, the method comprising: (a) obtaining, from one or more in-vehicle data sources, a first driving profile representing utilization of power consumers in the vehicle; (b) calculating an Electro-Magnetic Field (EMF) data element, representing emission of EMF by the power consumers of the first driving profile; and (c) calculating a second driving profile based on (i) the first driving profile and (ii) the EMF data element, wherein the second driving profile represents another utilization of power consumers in the vehicle.

In some embodiments, the method further comprises communicating the second driving profile to a controller of the vehicle, wherein the controller is configured to operate at least one power consumer of the vehicle according to the transmitted, second driving profile. In some embodiments, the method further comprises repeating steps (a) to (c) at any time when the vehicle is operated.

In some embodiments, the method further comprises calculating a power consumption data element, representing electric power consumed by the power consumers of the first driving profile, and calculating the second driving profile further based on the power consumption data element. the method further comprises providing a plurality of driving profiles, each corresponding to a unique utilization of power consumers in the vehicle; calculating one or more similarity metric values, representing similarity between the first driving profile and one or more respective driving profiles of the plurality of driving profiles; and selecting a subset of the plurality of driving profiles based on the calculated similarity metric values.

In some embodiments, the method further comprises selecting the second driving profile from the subset plurality of driving profiles based on at least one selection rule, wherein said selection rule represents a restriction of at least one of (a) the emission of EMF, as represented by the EMF data element, and (b) the power consumption, as represented by the power consumption value.

In some embodiments, calculating the second driving profile comprises: providing a plurality of driving profiles, each corresponding to a unique utilization of power consumers in the vehicle; clustering the plurality of driving profiles into a plurality of profile clusters, based on a similarity metric, said similarity metric representing similarity between driving profiles; associating the first driving profile to a profile cluster of the plurality of profile clusters based on the similarity metric; and selecting the second driving profile among the driving profile of the associated profile cluster based at least one selection rule. In some embodiments, the selection rule represents a restriction of at least one of (a) the emission of EMF, as represented by the EMF data element, and (b) the power consumption, as represented by the power consumption value.

Some additional aspects of the invention may be related to a method of managing utilization of power consumers in a vehicle, by at least one processor, the method comprising: obtaining, from one or more in-vehicle data sources, a first driving profile representing utilization of power consumers in the vehicle; calculating a power consumption data element, representing power consumption by the power consumers of the first driving profile; and calculating a second driving profile based on (i) the first driving profile and (ii) the power consumption data element, wherein the second driving profile represents another utilization of power consumers in the vehicle.

In some embodiments, the method further comprises communicating the second driving profile to a controller of the vehicle, wherein the controller is configured to operate at least one power consumer of the vehicle according to the transmitted, second driving profile. In some embodiments, the method further comprises repeating steps (a) to (c) at any time when the vehicle is operated.

In some embodiments, the method further comprises calculating Electro-Magnetic Field (EMF) data element, representing emission of EMF by the power consumers of the first driving profile, and calculating the second driving profile further based on the EMF data element.

In some embodiments, the method further comprises providing a plurality of driving profiles, each corresponding to a unique utilization of power consumers in the vehicle; calculating one or more similarity metric values, representing similarity between the first driving profile and one or more respective driving profiles of the plurality of driving profiles; and selecting a subset of the plurality of driving profiles based on the calculated similarity metric values.

In some embodiments, the method further comprises selecting the second driving profile from the subset plurality of driving profiles based on at least one selection rule, wherein said selection rule represents a restriction of at least one of (a) the emission of EMF, as represented by the EMF data element, and (b) the power consumption, as represented by the power consumption value.

In some embodiments, calculating the second driving profile comprises: providing a plurality of driving profiles, each corresponding to a unique utilization of power consumers in the vehicle; clustering the plurality of driving profiles into a plurality of profile clusters, based on a similarity metric, said similarity metric representing similarity between driving profiles; associating the first driving profile to a profile cluster of the plurality of profile clusters based on the similarity metric; and selecting the second driving profile among the driving profile of the associated profile cluster based at least one selection rule. In some embodiments, the selection rule represents a restriction of at least one of (a) the emission of EMF, as represented by the EMF data element, and (b) the power consumption, as represented by the power consumption value.

Some additional aspects of the invention may be directed to a method of data collection and modeling of power consumers in a vehicle, comprising: receiving a first driving profile; receiving one or more Electro-Magnetic Field (EMF) emission vectors, from one or more sensors, the emission is generated by one or more power consumers of the vehicle during the first driving profile; calculating a first data element, representing emission of EMF by the power consumers of the first driving profile; and storing the first data element in a cloud based storage.

In some embodiments, the method may further include, receiving a second driving profile; receiving one or more Electro-Magnetic Field (EMF) emission vectors, from the one or more sensors, the emission is generated by one or more power consumers of the vehicle during the second driving profile; calculating a second data element, representing emission of EMF by the power consumers of the second driving profile; and storing the second data element in the cloud-based storage.

In some embodiments, the method may further include, generating an Energy Profile matrix comprising two or more energy profiles; and generating an EMF emission matrix comprising two or more data elements.

In some embodiments, the method may further include receiving additional data from other sensors and wherein the calculating of the first data element is also based on the additional data.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram, depicting a system for managing utilization of power consumers in a vehicle according to some embodiments of the invention;

FIG. 2A is a block diagram, depicting a system for data collection and modeling for the system of managing utilization of power consumers in a vehicle, according to some embodiments of the invention;

FIG. 2B is an illustration of an nonlimiting example for, areas in a vehicle at which EMF levels are to be measured by sensors included in the system for data collection and modeling of FIG. 2A, according to some embodiments of the invention;

FIG. 3 is a block diagram, depicting a computing device which may be included in a system for managing the utilization of power consumers in a vehicle according to some embodiments of the invention;

FIG. 4 is a flowchart of a method of managing the utilization of power consumers in a vehicle in order to reduce EMF in the vehicle according to some embodiments of the invention;

FIG. 5 is a flowchart of a method of managing the utilization of power consumers in a vehicle in order to reduce power consumption according to some embodiments of the invention;

FIG. 6 is a flowchart of a method of data collection and modeling of power consumers in a vehicle according to some embodiments of the invention; and

FIG. 7 shows graphs of measured EMF and power consumption of a consumer during 2 different driving profiles according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, “estimating”, “inferring”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transeatory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term set when used herein can include one or more items. Unless explicitly stated, the method embodiments described herein are not constrained to a particular order or sequence. Additionally, some of the described method embodiments or elements thereof can occur or be performed simultaneously, at the same point in time, or concurrently.

As used herein, a Consumer is any device (e.g., electronic component, electromechanical component, etc.) which consumes power from the vehicle's High Voltage (HV) or Low Voltage (LV) batteries. Some nonlimiting examples for consumers include: electric engines, air conditioners, seat heating, inverters, converters, wishers, 12V battery, etc. Consumers also emit EMF.

As used herein, a Driving Profile includes a set of consumers operating simultaneously at specific driving conditions and their respective power consumptions under that specific driving condition. For example, a deriving profile may include the electric engine while the car drives at a specific speed, and simulations operating AC and wisher at a specific mode. When the vehicle is operated (e.g., traveling, standing while at least one consumer is working and the like), different driving profiles are operative at different times.

As used herein an Energy Profile is the cumulative energy consumption at each driving profile. The energy profile changes with time.

As used herein an Energy Profile matrix is a set of values or a set of functions that indicates the power consumption per driving profile.

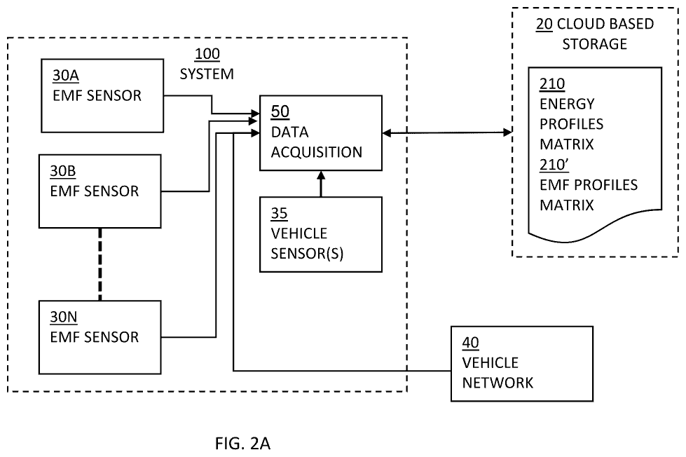

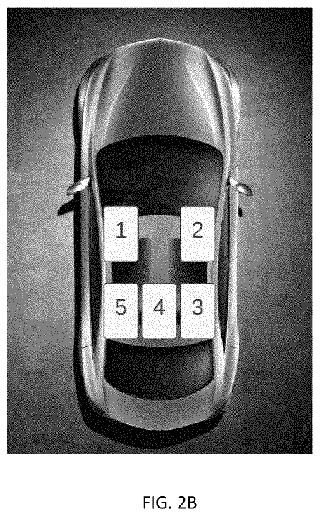

As used herein an EMF Emissions Profile is the sum of all magnetic fields per frequency in one frequency measurement scan at a certain location in the vehicle based on standards such as ICNIRP Standard for General Public, 1998. A Nonlimiting example for locations in the vehicle is given in FIG. 2B, discussed hereinbelow. The EMF profile changes with time.

As used herein EMF Emissions matrix is a set of values of a set of functions that indicates the EMF emissions per driving profile at various locations in the vehicle.

As used herein, a “vehicle” may be any form of transportation that includes one or more consumers. For example, a vehicle may be, an electric car, a hybrid car, an electric bus, an electric train, an electric ship, an electric airplane, an electric drone, an electric bike, an electric scooter, a maglev train, an elevator, a moving stairway, a roller conveyor, a treadmill, and the like. A “vehicle” may alternatively be any form of enclosure a human may be in, including for fitness or medical reasons. for example, solar system of photovoltaic panels and inverters.

As used herein, a frequency may refer to the entire EM frequency spectrum. More specifically, the frequency spectrum may be defined according to the IEC standard 62764-1, for example, 1 Hz-400 KHz which were found to be the frequency band at which most of the electrical components of the vehicle emit magnetic flux. Alternatively, the frequency spectrum may be 1-1000 KHz.

Embodiments of the present invention disclose a method and a system for of managing utilization of power consumers in an electric vehicle. The system may include a software to be uploaded into a controller located in the vehicle, that can determine the EMF profile and energy consumption profile in real-time based on the real-time driving profile. Such a “virtual sensor” may allow the determination of the EMF profile and energy consumption profile, without the need to receive real-time measurements from any physical sensor.

The determination of the real-time EMF profile and energy consumption profile may allow for optimizing the power consumers in the electric vehicle (e.g., reducing EMF and energy consumption).

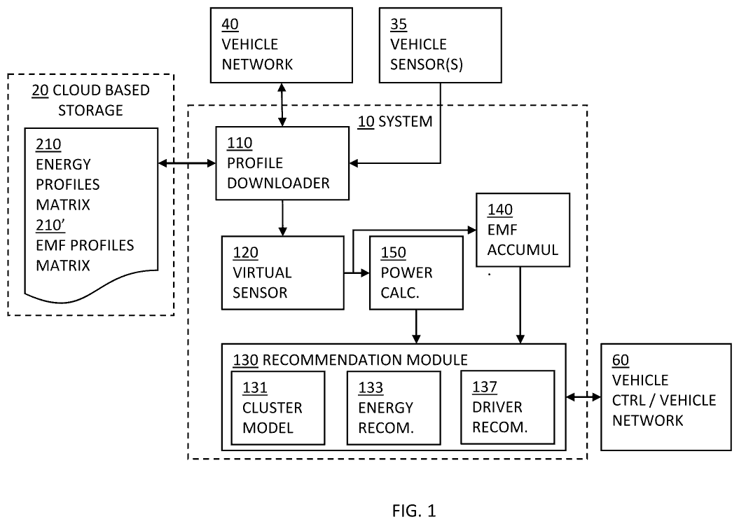

Reference is now made to FIG. 1, which is a block diagram of a system 10 for managing utilization of power consumers in a vehicle according to some embodiments of the invention. System 10 may be included in one of the vehicle's controllers/vehicle network 60 or may be an independent controller located in the vehicle. System 10 may communicate with vehicle network 40. In one example, vehicle network 40 is the vehicle's Controller Area Network (CAN) bus 40, which is the standard communication protocol that allows microcontrollers and devices (e.g., consumers) in the vehicle to communicate with each other's applications without a host computer. In another example, vehicle network 40 is the Ethernet or any other suitable vehicle network. In some embodiments, system 10 may obtain from vehicle network 40 a first driving profile representing utilization of power consumers in the vehicle.

In some embodiments, the first driving profile may include a set of consumers that are currently active in the vehicle, for example, the front engine, the rear engine, a seat heating, windscreen wipers, the audio system, air conditioning, and all the mandatory device, such as, safety units (e.g., powertrain system, ADAS/AD system, infotainment system and the like). The first profile may further include the mode/state at which each consumer works, for example, the speed of the vehicle (or rotational speed of the engine), the speed of the windscreen wipers, the mode of the seat heating, etc.

System 10 may be in communication with a cloud-based storage 20 for receiving Energy Profile matrix 210 and/or EMF emission matrix 210′. A system 100 for the equation and modeling of Energy Profile matrix 210 and/or EMF emission matrix 210′ is discussed herein below with respect to FIGS. 2A and 2B. In some embodiments, Energy Profile matrix 210 and/or EMF emission matrix 210′ may be downloaded into system 10 using a profile downloader 110. In some embodiments, prior to downloading Energy Profile matrix 210 and/or EMF emission matrix 210′, the size of data may be reduced using any known algorithm, for example, using a bitmap, a set of functions, each one handles a different profile and the like.

System 10 may further include a virtual sensor 120. Virtual sensor 120 may be configured to calculate an Electro-Magnetic Field (EMF) data element, representing the emission of EMF by the power consumers of the first driving profile. For example, virtual sensor 120 may use EMF accumulator 140 to calculate the accumulative EMF emission profile for the first driving profile. EMF accumulator 140 may include EMF emission matrix 210′, and virtual sensor 120 may look for a correlation between the first driving profile and a corresponding EMF emission profile, measured by system 100 illustrated in FIG. 2A and discussed herein below.

Additionally or alternatively, virtual sensor 120 may calculate a power consumption data element, representing power consumption by the power consumers of the first driving profile. For example, virtual sensor 120 may use power calculator 150 to calculate power consumption profile for first driving profile. Power calculator 150 may include power consumption matrix 210, and virtual sensor 120 may look for a correlation between the first driving profile and a corresponding power consumption profile, measured by system 100 illustrated in FIG. 2A and discussed herein below.

System 10 may further include a recommendation module 130. Recommendation module 130 may be configured to calculate a second driving profile based on (i) the first driving profile and (ii) the EMF data element and/or the power consumption data element, wherein the second driving profile represents another utilization of power consumers in the vehicle. In some embodiments, recommendation module 130 may include a clustering model 131 configured to: provide a plurality of driving profiles, each corresponding to a unique utilization of power consumers in the vehicle; cluster the plurality of driving profiles into a plurality of profile clusters, based on a similarity metric, said similarity metric representing similarity between driving profiles; associate the first driving profile to a profile cluster of the plurality of profile clusters based on the similarity metric; and select the second driving profile among the driving profile of the associated profile cluster based at least one selection rule. In some embodiments, said selection rule represents a restriction of at least one of (a) the emission of EMF, as represented by the EMF data element, and (b) the power consumption, as represented by the power consumption value. For example, the selected rule may include reducing the EMF emission in the passenger cabin, with no effect on safety devices, a minimal to no effect on the driving condition (e.g., speed, torque, etc.) and with minimal effect on the passengers' experience (e.g., air conditioning, audio performance, etc.).

Recommendation module 130 may further include an energy recommendation model 133 and a driver recommendation model 137. Energy recommendation model 133 may allow selecting the second driving profile based on optimizing the energy. For example, energy recommendation model 133 may include: providing a plurality of driving profiles, each corresponding to a unique utilization of power consumers in the vehicle; calculating one or more similarity metric values, representing similarity between the first driving profile and one or more respective driving profiles of the plurality of driving profiles; and selecting a subset of the plurality of driving profiles based on the calculated similarity metric values. Model 133 may further include selecting the second driving profile from the subset plurality of driving profiles based on at least one selection rule, wherein said selection rule represents a restriction (e.g., according to regulatory restrictions) of at least one of (a) the emission of EMF, as represented by the EMF data element, and (b) the power consumption, as represented by the power consumption value.

In some embodiments, driver recommendation model 137 may allow modifying the energy consumption of consumers related to the driver/passenger experience and not the driving conditions or safety. For example, driver recommendation model 137 may select the second driving profile to include changes in the power consumption and/or EMF emissions in consumers such as, the seat heaters, air conditions, audio system, and the like. In some embodiments, driver recommendation model 137 may select the second driving profile to allow minimal changes in consumers, such as, engines, actuators etc., may be required in order to meet EMF safety regulations.

In some embodiments, recommendation module 130 may communicate the second driving profile to a controller of the vehicle (e.g., a vehicle controller/vehicle network 60). In some embodiments, controller/vehicle network 60 is configured to operate at least one power consumer of the vehicle according to the transmitted, second driving profile.

Reference is now made to FIG. 2A, which is a block diagram for a system 100 for data collection and modeling of the system of managing utilization of power consumers in a vehicle, according to some embodiments of the invention. System 100 may be used to perform data collection or modeling related to the behavior of EMF at various locations in the vehicle at various driving profiles. Additionally or alternatively, system 100 may be configured to perform data collection or modeling related to the total power consumption at various driving profiles.

System 100 may include one or more EMF sensors 30A-30N located at various locations in the vehicle, for example, the locations illustrated in FIG. 2B. In some embodiments, sensors 30A-30N may include any sensor configured to detect an emission vector of magnetic flux density generated by a consumer of the vehicle. In some embodiments, units 30A-30N may each include a single magnetic flux sensor configured to measure a magnetic flux pattern at various frequencies. For example, the sensors may be, NARDA EHP-50F, Anisotropic Magneto-resistive (AMR) sensors, such as Honeywell HMC104, available from Honeywell, Hall Effect sensors, such as DRV5053 available from Texas, Instruments, and the like. In a non-limiting example, the sensor may be a magnetic field sensor that includes a 3 axis coil sensor and a computing system. In some embodiments, units 30A-30N may measure magnetic flux patterns at micro-Tesla or milligauss. In some embodiments, other sensors may be included or communicate with system 100, for example, Wireless Power Transfer (WPT) for smartphone charging, speakers, or other vehicle sensors with signal processing capabilities.

In some embodiments, one or more sensors 30A-30N may be assembled at a reference location (e.g., the locations illustrated in FIG. 2B) in the vehicle, for example, near the driver's wheel, below the driver's chair, and the like.

In some embodiments, one or more sensors 30A-30N may be assembled at the closest assembling location to a consumer. For example, a sensor 30A may be assembled on the envelope of the vehicle's electric motors (e.g., rear motor and/or front motor). In another example, a sensor 30B may be attached to a wire of the vehicle. In yet another example, a sensor 30C may be attached to the AC system of the vehicle.

System 100 may include one or more vehicle sensors 35, for example, configured to directly measure the electric power consumption of one or more consumers of the vehicle. For example, vehicle sensors 35 may be an amperemeter, voltmeter, or any electric power sensor. In some embodiments, vehicle sensor 35 may be in electric connection to at least one consumer. Additionally, other vehicle sensors 35 may be included in system 100, for example, weight sensor, thermometers, tire pressure sensors, humidity sensors, motion and location sensors, such as, GPS devices, GNSS devices, etc., accelerometers, and the like.

In some embodiments, system 100 may be in communication with vehicle network 40.

In some embodiments, system 100 may include a data acquisition module 50, configured to receive information from EMF sensors 30A-30N, vehicle sensor(s) 35, and vehicle network 40. Data acquisition module 50 may correlate between various driving profiles received from vehicle network 40 and measurements measured by EMF sensors 30A-30N and/or vehicle sensor(s) 35. In some embodiments, for each driving profile a corresponding EMF emission profile may be calculated and/or a corresponding power consumption profile.

In some embodiments, the correlation may be conducted at a cloud-based storage 20. In some embodiments, cloud-based storage 20 may only store the correlations, for example as an Energy Profile matrix 210 and/or EMF emission matrix 210′.

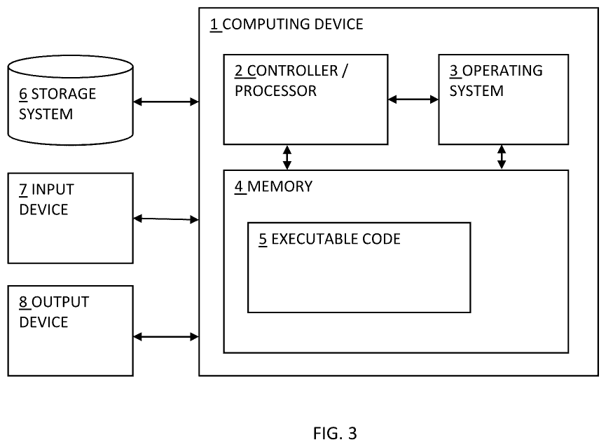

Reference is now made to FIG. 3, which is a block diagram depicting a computing device, which may be included within a system for managing utilization of power consumers in a vehicle, according to some embodiments. A computing device, such as device 1 may be included in the vehicle's computing system. In some embodiments, more than one computing device 1 may be included in the vehicle's computing system.

Computing device 1 may include a controller 2 that may be, for example, a central processing unit (CPU) processor, a chip or any suitable computing or computational device, an operating system 3, a memory 4, executable code 5, a storage system 6, input devices 7 and output devices 8. Controller 2 (or one or more controllers or processors, possibly across multiple units or devices) may be configured to carry out methods described herein, and/or to execute or act as the various modules, units, etc. More than one computing device 1 may be included in, and one or more computing devices 1 may act as the components of, a system according to embodiments of the invention.

Operating system 3 may be or may include any code segment (e.g., one similar to executable code 5 described herein) designed and/or configured to perform tasks involving coordination, scheduling, arbitration, supervising, controlling, or otherwise managing the operation of computing device 1, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory 4 may be or may include, for example, a Random Access Memory (RAM), a read-only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 4 may be or may include a plurality of, possibly different memory units. Memory 4 may be a computer or processor non-transeatory readable medium, or a computer non-transeatory storage medium, e.g., a RAM. In one embodiment, a non-transeatory storage medium such as memory 4, a hard disk drive, a solid-state disk, a flash memory, another storage device, etc. may store instructions or code which when executed by a processor may cause the processor to carry out methods as described herein, for example, a method of managing utilization of power consumers in a vehicle.

Executable code 5 may be any executable code, e.g., an application, a program, a process, task, or script. Executable code 5 may be executed by controller 2 possibly under the control of operating system 3. For example, executable code 5 may be an application that may detect a maintenance problem in a vehicle as further described herein. Although, for the sake of clarity, a single item of executable code 5 is shown in FIG. 3, a system according to some embodiments of the invention may include a plurality of executable code segments similar to executable code 5 that may be loaded into memory 4 and cause controller 2 to carry out methods described herein, for example, a method of managing utilization of power consumers in a vehicle.

Storage system 6 may be or may include, for example, a flash memory as known in the art, a memory that is internal to, or embedded in, a microcontroller or chip as known in the art, a hard disk drive, a CD-Recordable (CD-R) drive, a Blu-ray disk (BD), a universal serial bus (USB) device or other suitable removable and/or fixed storage unit. For example, parameters of the vehicle, (virtual) meshing of the vehicle, the location of EM sensors, and/or the locations of radiating components may be stored in storage system 6 and may be loaded from storage system 6 into memory 4 where it may be processed by controller 2. In some embodiments, some of the components shown in FIG. 3 may be omitted. For example, memory 4 may be a non-volatile memory having the storage capacity of storage system 6. Accordingly, although shown as a separate component, storage system 6 may be embedded or included in memory 4. In some embodiments, storage system 6 may be a cloud base storage system.

Input devices 7 may be or may include any suitable input devices, components, or systems, e.g., a detachable keyboard or keypad, a mouse, and the like. Output devices 8 may include one or more (possibly detachable) displays or monitors, speakers, and/or any other suitable output devices. Any applicable input/output (I/O) devices may be connected to Computing device 1 as shown by blocks 7 and 8. For example, a wired or wireless network interface card (NIC), a universal serial bus (USB) device, or an external hard drive may be included in input devices 7 and/or output devices 8. It will be recognized that any suitable number of input devices 7 and output device 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., controllers similar to controller 2), a plurality of input units, a plurality of output units, a plurality of memory units, and a plurality of storage units.

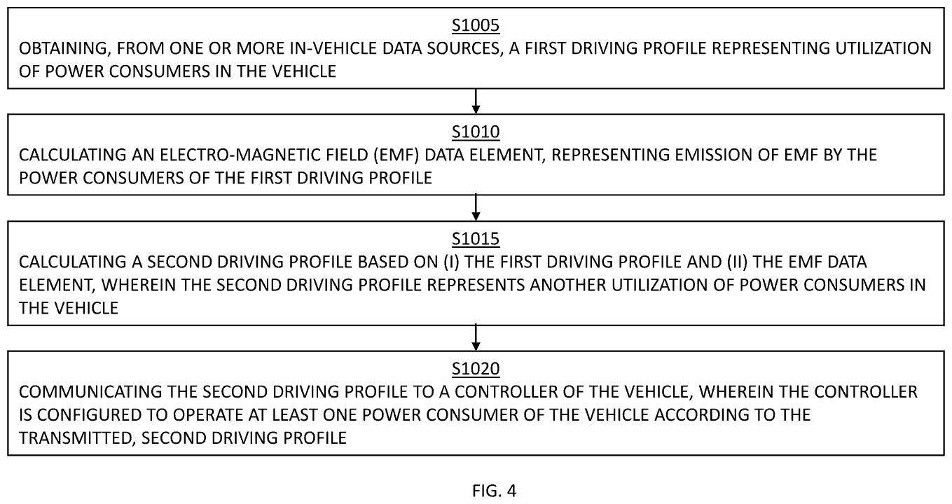

Reference is now made to FIG. 4 which is a flowchart of a method of managing utilization of power consumers in a vehicle according to some embodiments of the invention. The method of FIG. 4 may be performed by a controller included in system 10, for example, computing device 1, at any time when the vehicle is operated (e.g., while traveling, standing when at least one consumer is operating, etc.). In step 1005, a first driving profile representing the utilization of power consumers in the vehicle may be obtained from one or more in-vehicle data sources. For example, a plurality of driving profiles may be obtained from vehicle network 40. Each driving profile may include a set of power consumers Cl-Cn operated at specific operation modes, which results in the power consumption of each customer. A nonlimiting example for a driving profile is given in table 2.

TABLE 2

| | Consumption |
|---|---|
| Consumer | (mA) |
| c1 | 100 |
| c2 | 200 |
| c3 | 5 |
| c4 | 40 |
| c5 | 67 |
| c6 | 350 |
| c-n | |

In step 1010, an Electro-Magnetic Field (EMF) data element, representing the emission of EMF by the power consumers of the first driving profile, may be calculated, for example, using virtual sensor 120 and EMF accumulator 140. The EMF data element may include the EMF profile with includes the accumulated EMF at various frequencies at one or more locations in the vehicle. For example, the EMF data element may include the accumulated EMF at 1 to 400 Hz at the driver's seat (location 1 in FIG. 2B).

In some embodiments, virtual sensor 120 may be used also for calculating a power consumption data element representing electric power consumed by the power consumers of the first driving profile. For example, power consumption calculator 150 may calculate the power consumption data element to include the accumulated power consumption of all the consumers included in the first driving profile.

In some embodiments, the EMF data element and/or the power consumption data element may be calculated based on data acquired and modeled during a data acquisition stage, conducted for example, by system 100 of FIG. 2A and discussed herein above. During the data acquisition stage various driving profiles may be tested and the EMF profile at one or more locations if the vehicle may be measured, using for example, EMF sensors 30A-30N. Table 2, is a nonlimiting example for such data collection, collected for various driving profiles and EMF profiles at the diver's seat (location 1, in FIG. 2B). At the nonlimiting example of table 2, the EMF data element is the peak of the EMF. The data element may further include if the EMF profile is above (>100%) or below (<100%) of the allowed EMF accumulation according to the regulations. Table 3 further includes the energy consumption profile (e.g., the energy accumulation from all consumers) in each profile.

TABLE 3

| | | Energy | | EMF |
|---|---|---|---|---|
| Driving | Combined | consumption | Peak MF | Emissions |
| Profile | Consumers | Profiles (mA) | (micro-Tesla) | Profiles |
| p1 | c1, c3, c6 | 455 | 42 | <100% |
| p2 | c1, c3, c4 | 245 | 31 | <100% |
| p3 | c1, c2, c3, | 695 | 73 | >100% |
| | c4, c6 | | | |

In some embodiments, during the data acquisition and modeling stage, a plurality of driving profiles may be tested at specific driving scenarios. For example, in profiles P1, P2, and P3, c1 is the rear-engine, c3 is the front-engine, c6 the air condition system, c4 the seat heating, and c2 the windscreen wipers. All three profiles may be tested when the vehicle drives at a constant speed of 100 Kph.

Table 4 shows a nonlimiting example, for such data collection. Each measurement corresponds to a single profile operated at a specific scenario (e.g., 100 Kph steady driving, regular charging, town tour, etc.).

TABLE 4

Summary

| Scenarios | total measurements | # >100% |
|---|---|---|
| 100 kph steady drive | 428 | 17 |
| 20-70 kph acceleration | 224 | 10 |
| charging | 601 | 63 |
| 70-20 kph braking | 173 | 24 |
| town tour | 2922 | 34 |
| Total | 4348 | 148 |

Table 4, shows the number of tested profiles for each scenario, and the percentage of the measurement that accedes the EMF levels under the ICNIRP regulation.

In some embodiments, the outcome of the data acquisition and modeling stage is Energy Profile matrix 210 and/or EMF emission matrix 210′. EMF emission matrix 210′. EMF emission matrix 210′ may be stored in cloud-based storage 20.

From cloud-based storage 20 EMF emission matrix 210′ and/or Energy Profile matrix 210 may be uploaded to profile downloader 110.

In step 1015, a second driving profile may be calculated based on (i) the first driving profile and (ii) the EMF data element, wherein the second driving profile represents another utilization of power consumers in the vehicle. For example, recommendation module 130 may calculate the second driving profile using any one of: clustering model 131, energy recommendation model 133, and driver recommendation model 137.

In some embodiments, in order to calculate the second driving profile, a plurality of driving profiles may be provided by virtual sensor 120, each corresponding to a unique utilization of power consumers in the vehicle. The computing device of system 10 may then calculate one or more similarity metric values, representing similarity between the first driving profile and one or more respective driving profiles of the plurality of driving profiles. In some embodiments, a subset of the plurality of driving profiles may be selected based on the calculated similarity metric values. For example, all profiles associated with a town tour driving when the air conditions is working.

In some embodiments, selecting the second driving profile from the subset plurality of driving profiles based on at least one selection rule, wherein said selection rule represents a restriction of at least one of (a) the emission of EMF, as represented by the EMF data element, and (b) the power consumption, as represented by the power consumption value. For example, the second driving profile may be selected to emit the lowest EMF emission.

In some embodiments, clustering model 131 may be performed in order to calculate the second driving profile. In some embodiments, the clustering model may include: providing a plurality of driving profiles, each corresponding to a unique utilization of power consumers in the vehicle; clustering the plurality of driving profiles into a plurality of profile clusters, based on a similarity metric, said similarity metric representing similarity between driving profiles; associating the first driving profile to a profile cluster of the plurality of profile clusters based on the similarity metric; and selecting the second driving profile among the driving profile of the associated profile cluster based at least one selection rule. In some embodiments, the selection rule represents a restriction of at least one of (a) the emission of EMF, as represented by the EMF data element, and (b) the power consumption, as represented by the power consumption value.

In step 1020, the second driving profile may be communicated to a controller of the vehicle, wherein the controller is configured to operate at least one power consumer of the vehicle according to the transmitted, second driving profile. For example, recommendation module 130 may send the calculated second driving profile to vehicle controller/vehicle network 60, which may change the electric power consumption in at least one consumer. For example, vehicle controller/vehicle network 60 may reduce the power provided the seat heating.

In some embodiments, steps 1005 to 1020 may be repeated (e.g., constantly repeated) when the vehicle is operated.

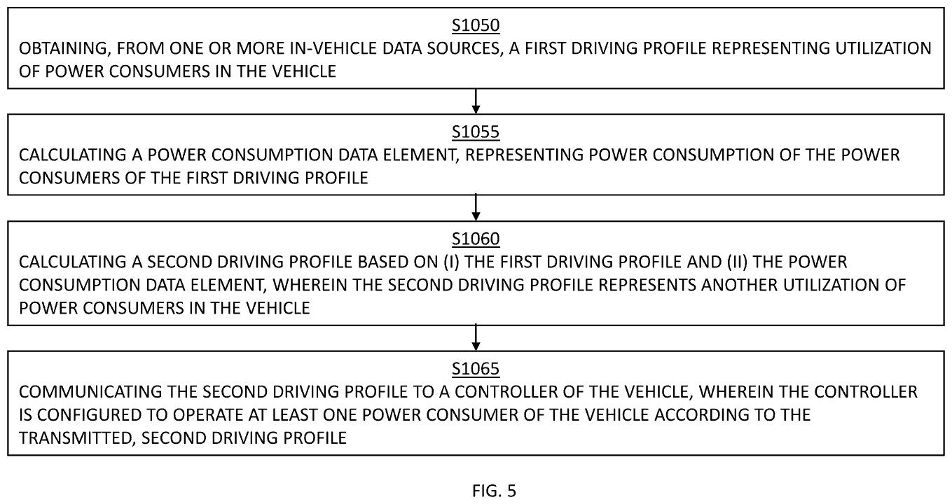

Reference is now made to FIG. 5 which is a flowchart of a method of managing utilization of power consumers in a vehicle according to some embodiments of the invention. The method of FIG. 5 may be performed by a controller included in system 10, for example, computing device 1, at any time when the vehicle is operated (e.g., while traveling, standing when at least one consumer is operating, etc.). In step 1050, a first driving profile representing utilization of power consumers in the vehicle, may be obtained from one or more in-vehicle data sources. Step 1050 is substantially similar to step 1005 of the method of FIG. 4.

In step 1055, a power consumption data element, representing power consumption by the power consumers of the first driving profile may be calculated, for example, using power consumption calculator 150 and virtual sensor 120. In some embodiments, EMF data element representing EMF emissions by the power consumers of the first driving profile may be calculated using EMF accumulator 140.

In some embodiments, the EMF data element and/or the power consumption data element may be calculated based on data acquired and modeled during a data acquisition stage, conducted for example, by system 100 of FIG. 2A, as discussed above with respect to step 1010 of FIG. 4 and applicable to step 1055 as well.

In step 1060, a second driving profile may be calculated based on (i) the first driving profile and (ii) the power consumption data element, wherein the second driving profile represents another utilization of power consumers in the vehicle. For example, recommendation module 130 may calculate the second driving profile using any one of: clustering model 131, energy recommendation model 133 and driver recommendation model 137, as discussed above with respect to step 1015 of FIG. 4 and applicable to step 1060 as well.

In step 1065, the second driving profile may be communicated to a controller of the vehicle, wherein the controller is configured to operate at least one power consumer of the vehicle according to the transmitted, second driving profile. For example, recommendation module 130 may send the calculated second driving profile to vehicle controller/vehicle network 60, which may change the electric power consumption in at least one consumer. For example, vehicle controller/vehicle network 60 may reduce the power provided the air condition system.

In some embodiments, steps 1050 to 10650 may be repeated (e.g., constantly repeated) when the vehicle is operated.

In some embodiments, the method may further allow to select the driving profile in order for the vehicle to travel from location A to location B. In some embodiments, a user may enter a destination and recommendation module 130 may receive from vehicle controller/vehicle network 60 the expected maximum distance of the vehicle based on the capacity battery. If the distance form location A to location B is greater than the expected maximum distance, recommendation module 130 may select a set of driving profiles that may reduce the power consumption such that the vehicle may travel from location A to location B without the need for a recharge.

In some embodiments, if the driver changes the driving profile, recommendation module 130 may reselect new driving profiles in order to ensure that the vehicle may travel from location A to location B without the need for a recharge.

In some embodiment, recommendation module 130 may further be updated during the lifetime of the vehicle. For example, an updated Energy Profile matrix 210 and/or EMF emission matrix 210′ may be uploaded via profile downloader 110, each time the vehicle enters a maintenance facility. The updated Energy Profile matrix 210 and/or EMF emission matrix 210′ may be collected using system 100 in the maintenance facility. For example, sensors 30a-30n may be placed in various locations in the vehicle and data may be collected at various simulated driving profiles. The simulated driving profiles may simulate real driving profiles in the maintenance facility.

Additionally or alternatively, the updated Energy Profile matrix 210 and/or EMF emission matrix 210′ may be collected using system 100 assembled in several selected vehicles from a group of vehicles, for example, 10-20 cars from 10000 cars of the same model and type. These selected vehicles may travel in various scenarios activating various driving profiles while creating corresponding real-time EMF profiles and power consumption profiles. The collected data from at least some of the selected vehicles may periodically be collected and analyzed in order to update the Energy Profile matrix 210 and/or EMF emission matrix 210′. The new updated Energy Profile matrix 210 and/or EMF emission matrix 210′ may then be loaded system 10 of other vehicles.

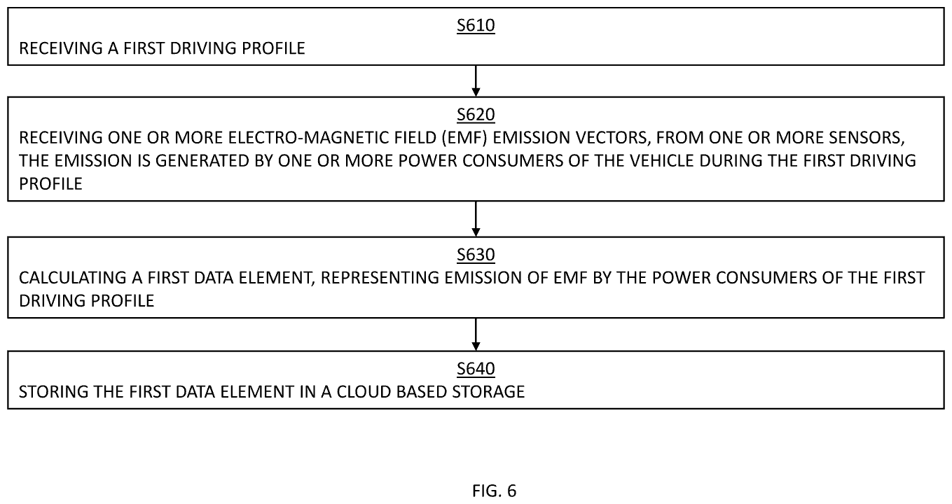

Reference is now made to FIG. 6 which is a flowchart of a method of data collection and modeling of power consumers in a vehicle according to some embodiments of the invention. The method of FIG. 6 may be performed by a controller included in system 10, for example, computing device 1, at any time when the vehicle is operated (e.g., while traveling, standing when at least one consumer is operating, etc.).

In step 610, a first driving profile may be received, for example, from vehicle network 40. The first driving profile may include one or more consumers operating simultaneously at specific driving conditions and their respective power consumptions under that specific driving condition (e.g., accelerations, decelerations, etc.). For example, a deriving profile may include the electric engine while the car drives at a specific speed, and simulations operating AC and wisher at a specific mode. When the vehicle is operated (e.g., traveling, standing while at least one consumer is working and the like), different driving profiles are operative at different times.

In step 620, one or more EMF emission vectors, from one or more sensors, the emission is generated by one or more power consumers of the vehicle during the first driving profile. For example, the controller may receive measurements of EMF emission vector(s) from one or more EMF sensors 30A to 30N during the first driving profile.

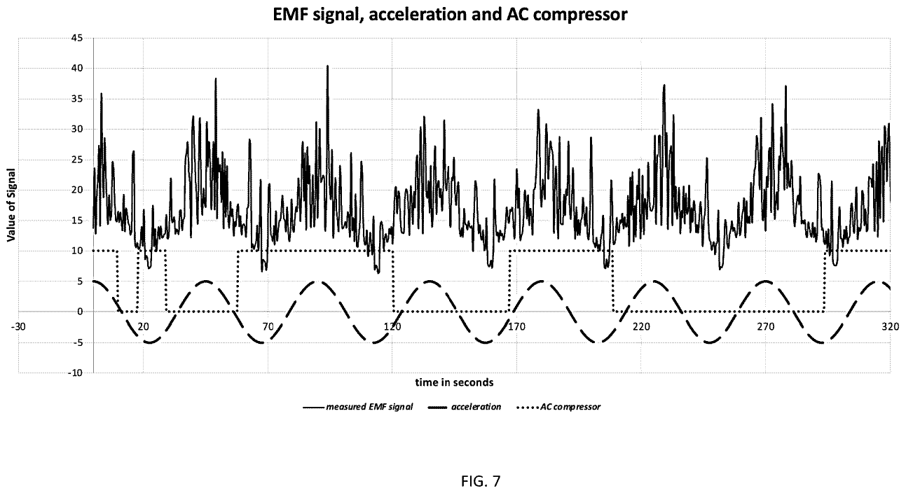

In some embodiments, additional data may be received from other sensors, such as vehicle sensors 35, as discussed with respect to FIG. 2A and shown in the graph of FIG. 7.

In step 630, a first data element may be calculated, the first data element representing emission of EMF by the power consumers of the first driving profile. For example, the first data element may include the accumulated EMF emission vector at a specific location in the vehicle.

In step 640, the first data element may be stored in a cloud-based storage, for example, cloud-based storage 20.

In some embodiments, additional the first data element may further include additional data received from the vehicle's sensors and/or the vehicle's network.

In some embodiments, steps 610 to 640 may be repeated for a second driving profile, third driving profile, etc. In some embodiments, an Energy Profile matrix (e.g., Energy Profile matrix 210) may be generated. The Energy Profile matrix comprising two or more energy profiles. In some embodiments, an EMF emission matrix (e.g., EMF emission matrix 210′) may be generated. The EMF emission matrix comprising two or more data elements.

Reference is now made to FIG. 7 which graphs of measured EMF and power consumption of a consumer during 2 different driving profiles according to some embodiments of the invention. Two alternating driving profiles were tested in family electric car having 410 horsepower. The alternating driving profiles are accelerating and decelerating (denoted by the dashed line) while the air condition (AC) system is working. The power consumption of the AC compressor (denoted as the dotted line) was received from the vehicle's network. This was done in a repetitive mode with acceleration and braking cases repeatedly where the measured EMF varies between each cycle.

The EMF emission was measured by a sensor located behind the back seat. As shown the influence of both acceleration and deceleration have major effect on the EMF emission. The fluctuations and differences between EMF emission in similar cycles of acceleration and deceleration are explained by the application of the AC compressor which is not in synchronized with the acceleration. Therefore, both the acceleration and deceleration and the AC compressor consumption impact the effective energy consumption.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A method of managing utilization of power consumers in a vehicle, by at least one processor, the method comprising:
(a) obtaining, from one or more in-vehicle data sources, a first driving profile representing utilization of power consumers in the vehicle;
(b) calculating an Electro-Magnetic Field (EMF) data element, representing emission of EMF by the power consumers of the first driving profile;
(c) calculating a second driving profile based on (i) the first driving profile and (ii) the EMF data element, wherein the second driving profile represents another utilization of power consumers in the vehicle; and
(d) communicating the second driving profile to a controller of the vehicle, wherein the controller is configured to operate at least one power consumer of the vehicle according to the transmitted, second driving profile.

2. (canceled)

3. The method of claim 1, further comprising:
repeating steps (a) to (c) at any time when the vehicle is operated.

4. The method according to claim 1, further comprising:
calculating a power consumption data element, representing electric power consumed by the power consumers of the first driving profile, and
calculating the second driving profile further based on the power consumption data element.

5. The method according to claim 1, further comprising:
providing a plurality of driving profiles, each corresponding to a unique utilization of power consumers in the vehicle;
calculating one or more similarity metric values, representing similarity between the first driving profile and one or more respective driving profiles of the plurality of driving profiles; and
selecting a subset of the plurality of driving profiles based on the calculated similarity metric values.

6. The method according to claim 1, further comprising selecting the second driving profile from the subset plurality of driving profiles based on at least one selection rule, wherein said selection rule represents a restriction of at least one of (a) the emission of EMF, as represented by the EMF data element, and (b) the power consumption, as represented by the power consumption value.

7. The method according to claim 1, wherein calculating the second driving profile comprises:
providing a plurality of driving profiles, each corresponding to a unique utilization of power consumers in the vehicle;
clustering the plurality of driving profiles into a plurality of profile clusters, based on a similarity metric, said similarity metric representing similarity between driving profiles;
associating the first driving profile to a profile cluster of the plurality of profile clusters based on the similarity metric; and
selecting the second driving profile among the driving profile of the associated profile cluster based at least one selection rule.

8. The method of claim 7, wherein said selection rule represents a restriction of at least one of (a) the emission of EMF, as represented by the EMF data element, and (b) the power consumption, as represented by the power consumption value.

9. A method of managing utilization of power consumers in a vehicle, by at least one processor, the method comprising:
(a) obtaining, from one or more in-vehicle data sources, a first driving profile representing utilization of power consumers in the vehicle;
(b) calculating a power consumption data element, representing power consumption by the power consumers of the first driving profile;
(c) calculating a second driving profile based on (i) the first driving profile and (ii) the power consumption data element, wherein the second driving profile represents another utilization of power consumers in the vehicle; and
(d) communicating the second driving profile to a controller of the vehicle, wherein the controller is configured to operate at least one power consumer of the vehicle according to the transmitted, second driving profile.

10. (canceled)

11. The method of claim 8, further comprising:
repeating steps (a) to (c) at any time when the vehicle is operated.

12. The method according to claim 9, further comprising:
calculating Electro-Magnetic Field (EMF) data element, representing emission of EMF by the power consumers of the first driving profile, and
calculating the second driving profile further based on the EMF data element.

13. The method according to claim 9, further comprising:
providing a plurality of driving profiles, each corresponding to a unique utilization of power consumers in the vehicle;
calculating one or more similarity metric values, representing similarity between the first driving profile and one or more respective driving profiles of the plurality of driving profiles; and
selecting a subset of the plurality of driving profiles based on the calculated similarity metric values.

14. The method according to claim 9, further comprising selecting the second driving profile from the subset plurality of driving profiles based on at least one selection rule, wherein said selection rule represents a restriction of at least one of (a) the emission of EMF, as represented by the EMF data element, and (b) the power consumption, as represented by the power consumption value.

15. The method according to claim 9, wherein calculating the second driving profile comprises:
providing a plurality of driving profiles, each corresponding to a unique utilization of power consumers in the vehicle;
clustering the plurality of driving profiles into a plurality of profile clusters, based on a similarity metric, said similarity metric representing similarity between driving profiles;
associating the first driving profile to a profile cluster of the plurality of profile clusters based on the similarity metric; and
selecting the second driving profile among the driving profile of the associated profile cluster based at least one selection rule.

16. The method of claim 15, wherein said selection rule represents a restriction of at least one of (a) the emission of EMF, as represented by the EMF data element, and (b) the power consumption, as represented by the power consumption value.

17.-20. (canceled)
